(19) United States
(12) Patent Application Publication
(10) Pub. No.: US 2026/0227568 A1
(43) Pub. Date: Aug. 6, 2026

(54) DISCRETE-TIME LIGHT SOURCES BASED ON INTEGRATED PHOTONICS

(71) Applicants: The General Hospital Corporation, Boston, MA (US); President and Fellows of Harvard College, Cambridge, MA (US)

(72) Inventors: Benjamin Vakoc, Arlington, MA (US); Norman Lippok, Somerville, MA (US); Marko Loncar, Belmont, MA (US); Gage Hills, Watertown, MA (US); Yaowen Hu, Cambridge, MA (US); John Davis, Cambridge, MA (US)

(21) Appl. No.: 19/150,878

(22) PCT Filed: Jan. 26, 2024
(86) PCT No.: PCT/US2024/013123

§ 371 Date: Jul. 24, 2025

Related U.S. Application Data
(60) Provisional application No. 63/481,624, filed on Jan. 26, 2023.

(51) Int. Cl. G02B 6/12; G02B 6/293

(52) U.S. Cl. CPC G02B 6/12007; G02B 2006/12109; G02B 2006/12142; G02B 6/29343; G02B 6/29395

(57) ABSTRACT

Optical coherence tomography (OCT) light source designs are described that utilize low-loss thin film lithium niobate (TFLN)-integrated photonic circuits. The circuits and laser cavities include one or more micro-resonators (MRR), Mach-Zehnder (MZ) filters, and Michelson (MC) filters to achieve the modulation requirements for OCT, namely high-performance and high-speed output tuning.

### CROSS REFERENCE TO RELATED APPLICATIONS

The present application is based on, claims priority to, and incorporates herein by reference in its entirety for all purposes, US Provisional Application Ser. No. 63/481,624, filed Jan. 26, 2023.

### STATEMENT OF GOVERNMENT SUPPORT

This invention was made with government support under 5R21EY031895-02 awarded by the National Institutes of Health (NIH). The U.S. government has certain rights in the invention.

### BACKGROUND

Optical coherence tomography (OCT) performance is bounded by the capabilities of the optical sources used to generate spatially coherent and wavelength-tuned imaging light. Traditionally, OCT has relied on light sources that incorporate a mechanical tuning element, such as a micro-electromechanical mirror or a rotating mirror. Mechanical elements limit the speed and agility of the output tuning. There has been significant progress in the development of active integrated photonic circuits. These photonic circuits direct light through various elements on nano-fabricated waveguides on a wafer. Traditionally, integrated photonics circuits are passive, meaning that the waveguides allow one to control where light propagates but offer minimal capability for modulating the properties of the light. Most integrated photonics use at most thermal tuning, which is extremely slow. This has prevented integrated photonic circuits from being used as a platform for creating light sources in OCT. Without high-speed modulation, using integrated photonics in wavelength-tuned sources for OCT can be challenging.

### SUMMARY OF THE INVENTION

The systems described herein overcome the above drawbacks and limitations of OCT light sources via new architectures for OCT light sources that utilize low-loss TFLN-integrated photonic circuits. Novel integrated phonic circuit designs are presented to achieve the modulation requirements for OCT. Complete laser architectures incorporating these photonic circuits are also presented. The integrated photonics circuits and laser architectures, although described here as sources for OCT, can also be used as a general wavelength tunable spectral filter and wavelength tunable light source for additional applications such as but not limited to ranging, spectroscopy and general sensing applications.

Recently, there has been progress in creating integrated photonic circuits on thin-film lithium niobate (TFLN), sometimes termed lithium niobate on insulator (LNOI). Lithium niobate is an active optical material that allows one to use voltage to modulate the phase of light. This voltage-to-phase conversion provides a critical building block for high-speed modulation and manipulation of light. Previously, nano-fabricated waveguides in TFLN exhibited a high optical loss (in dB per length) such that only very small circuits could be created. Recent advances have demonstrated low-loss TFLN waveguides, opening the door to more elaborate and complex integrated photonic circuits with built-in capabilities for active modulation. Largely, this low-loss TFLN technology is being used to create new devices for signaling and telecommunications.

Because TFLN has intrinsically high optical modulation bandwidth (well in excess of 10 GHz) and because one can create complex photonics circuits combining multiple elements, these OCT sources have the potential to achieve extremely high performance, measured in output modulation speed and agility. Further, because multiple functions can be incorporated into the integrated phonic circuit, the size and cost of the laser system can be minimized. Thus, embodiments of this disclosure can produce extremely high-performance OCT sources that can be manufactured at low cost and occupy small footprints. These are important advantages in existing and emerging OCT markets.

In one aspect of the present disclosure, an integrated photonic circuit is described. The circuit comprises an input, an output, and a plurality of micro-ring resonators (MRRs) disposed between the input and the output. Each of the plurality of MRRs includes an electrode and a heater, wherein the electrode is configured to shift the position of transmission peaks of an input transmission and the heater is configured to set the location of the transmission peaks when a voltage to the electrodes is zero. The MRRs further include a first MRR coupled to the input, the first MRR including a first heater and a first electrode, a second MRR coupled to the output, the second MRR including a second heater and a second electrode, and a controller coupled to the first heater, the first electrode, the second heater, and the second electrode. The controller is configured to control at least one of the first heater, the first electrode, the second heater, or the second electrode to emit light with a transmission peak at the output.

In another aspect of the present disclosure, a laser cavity is described. The laser cavity comprises the integrated photonic circuit of the immediately preceding paragraph, a delay, and a gain, wherein the integrated photonic circuit, delay, and gain are positioned in series within the laser cavity.

In another aspect of the present disclosure, an integrated photonic circuit is described. The circuit comprises an input, an output, and a micro-ring resonator (MRR) disposed between the input and the output. The MRR includes an electrode and a heater, wherein the electrode is configured to shift the position of transmission peaks of an input transmission and the heater is configured to set the location of the transmission peaks when a voltage to the electrodes is zero. The MRR further includes an MRR coupled to the input, the MRR including a heater and an electrode. The circuit further includes a plurality of Mach-Zehnder (MZ) filters disposed between the MRR and the output and configured to receive the transmission from the MRR. The MZ filters include two arms of differing lengths to create a path imbalance between them. The circuit further includes a controller coupled to the heater and the electrode, the controller being configured to control at least one of the heater or the electrode to emit light with a transmission peak at the output.

In still another aspect of the present disclosure, a method of operating an integrated photonic circuit is provided. The method includes: providing an integrated photonic circuit including: an input and an output, a plurality of micro-ring resonators (MRRs) disposed between the input and the output, each of the plurality of MRRs including an electrode and a heater, each electrode being configured to shift a position of a transmission peak of an input transmission and each heater being configured to set a location of the transmission peak when a voltage at the electrode is zero, and the MRRs including: a first MRR coupled to the input, the first MRR including a first heater and a first electrode, and a second MRR coupled to the output, the second MRR including a second heater and a second electrode; coupling a controller to the first heater, the first electrode, the second heater, and the second electrode; and controlling, using the controller, at least one of the first heater, the first electrode, the second heater, or the second electrode to emit light with a transmission peak at the output.

In yet another aspect of the present disclosure, a method of operating a laser cavity is provided. The method includes: providing the integrated photonic circuit of claim 22; and positioning the integrated photonic circuit, a delay, and a gain in series within the laser cavity.

In another aspect of the present disclosure, a method of operating an integrated photonic circuit is provided. The method includes: providing an integrated photonic circuit including: an input and an output; a micro-ring resonator (MRR) disposed between the input and the output, including an electrode and a heater, the electrode being configured to shift a position of a transmission peak of an input transmission and the heater being configured to set a location of the transmission peak when a voltage to the electrode is zero, the MRR being coupled to the input, the MRR including a heater and an electrode; disposing a plurality of Mach-Zehnder (MZ) filters between the MRR and the output, the MZ filters being configured to receive the transmission from the MRR, the MZ filters including two arms of differing lengths to create a path imbalance between them; coupling a controller the heater and the electrode; and controlling, using the controller, at least one of the heater or the electrode to emit light with a transmission peak at the output.

In another aspect of the disclosure, an integrated photonic circuit is provided. The circuit includes: an input and an output; a plurality of micro-ring resonators (MRRs) disposed between the input and the output, each of the plurality of MRRs including an electrode, each electrode being configured to shift a position of a transmission peak of an input transmission and to set a location of the transmission peak, the MRRs including: a first MRR coupled to the input, the first MRR including a first electrode, and a second MRR coupled to the output, the second MRR including a second electrode; and a controller coupled to the first electrode and the second electrode, the controller being configured to: control at least one of the first electrode or the second electrode to emit light with a transmission peak at the output.

In yet another aspect of the disclosure, an integrated photonic circuit is provided. The circuit includes: a plurality of micro-ring resonators (MRRs) disposed between the input and the output, the MRRs including: a first MRR coupled to the input, the first MRR including a first heater and a first electrode, and a second MRR coupled to the output, the second MRR including a second heater and a second electrode, the first electrode and the second electrode being configured to shift a position of a transmission peak of an input transmission, and the first heater and the second heater being configured to set a location of the transmission peak when a voltage at the electrode is zero; and a controller coupled to the first heater, the first electrode, the second heater, and the second electrode, the controller being configured to: control at least one of the first heater, the first electrode, the second heater, or the second electrode to emit light with a transmission peak at the output.

These aspects are nonlimiting. Other aspects and features of the systems and methods described herein will be provided below.

### BRIEF DESCRIPTION OF THE DRAWINGS

The foregoing features of embodiments will be more readily understood by reference to the following detailed description, taken with reference to the accompanying drawings, in which:

FIG. 1 is a schematic of an integrated photonic circuit, according to the present disclosure.

FIG. 2 shows plots of the spectral output for an integrated photonic filter with three total MRRs. The upper row shows the transmission response of each MRR over three comblines. The bottom row illustrates the suppression of two of the comblines.

FIG. 3 is a schematic of a laser cavity, according to aspects of the present disclosure.

FIG. 4 is a schematic of an integrated photonic circuit including an MRR and three MZ interferometers (MZI), according to aspects of the present disclosure.

FIG. 5A is a schematic of the integrated photonic circuit setup of FIG. 4 illustrating the selection of the optical output.

FIG. 5B shows plots of the transmission spectra of the MRR and each MZI (top row), and the combined transmissions showing the selection of a single combline of the MRR (bottom row).

FIG. 6A is an image of a fabricated integrated photonics filter (LNOI chip) on an electrical interface board with electrical connections leading to a cable at the lower side of the board.

FIG. 6B is an image of the LNOI chip of FIG. 6A.

FIG. 6C is an image of the electrode (E) and heater (H) overlays above the waveguides shown in FIG. 6B.

FIG. 6D is a plot of the optical output after the MRR (top row plots) and the drive signals for MZI1-MZI4 in the lower plots.

FIG. 6E shows the measured time-resolved optical output showing discrete stepping in frequency and time.

FIG. 7A is a schematic of laser cavity with the filter shown in FIG. 6A represented by the LNOI.

FIG. 7B shows the time (upper plot) and spectral (lower plot) output of the laser.

FIG. 7C is a schematic of an imaging interferometer configuration.

FIG. 7D shows exemplary en-face (left and center images) and cross-sectional image (right image) using the source.

FIG. 8A is a schematic of a thin-film lithium niobate (TFLN) filter chip within a laser cavity.

FIG. 8B is a series of plots of the optical power of light exiting the MRR (1^{st} plot), the sinusoidal spectral transmission of MZ1 (2^{nd} plot), the optical power of light exiting MZ1 (3^{rd} plot), the sinusoidal spectral transmission of MZ2 (4^{th} plot), the optical power of light exiting MZ2 (5^{th} plot), the sinusoidal spectral transmission of MZ3 (6^{th} plot), and the optical power of light exiting MZ3 (7^{th} plot).

FIG. 9A is a schematic of a conventional electro-optically controllable MZ filter that is based on an analog drive signal.

FIG. 9B is a schematic of an electro-optically controllable MZ filter that does not require a DAC but instead performs the digital-to-analog conversion in the optical domain using a sequence of electrodes with specific placements and lengths.

FIG. 9C is a digital encoding table to create 2⁴=16 phase differences in the MZ filter from −π, −7π/8 . . . , +7π/8.

FIG. 9D is an alternative electrode geometry to create a digitally controllable MZ filter.

FIG. 10 shows the optical power plots of a cascaded MZ filter configured with MZ FSRs that are powers of three of the MRR FSR. of the MRR output frequency comb (1^{st} plot), the transmission of MZ1 (2^{nd} plot), the transmitted spectrum of MZ1 (3^{rd} plot), the transmission of MZ2 (4^{th} plot), and the transmitted spectrum of MZ2 (5^{th} plot).

FIG. 11 is a schematic of a laser cavity with a TFLN filter chip using a MRR and a cascaded set of path imbalanced MZs following a power of three scaling.

FIG. 12 is a schematic of a cascaded filter design including Michelson (MC) interferometer.

### DETAILED DESCRIPTION

Disclosed herein are integrated photonic circuits and laser cavities configured to achieve high output modulation speed and agility performance OCT sources.

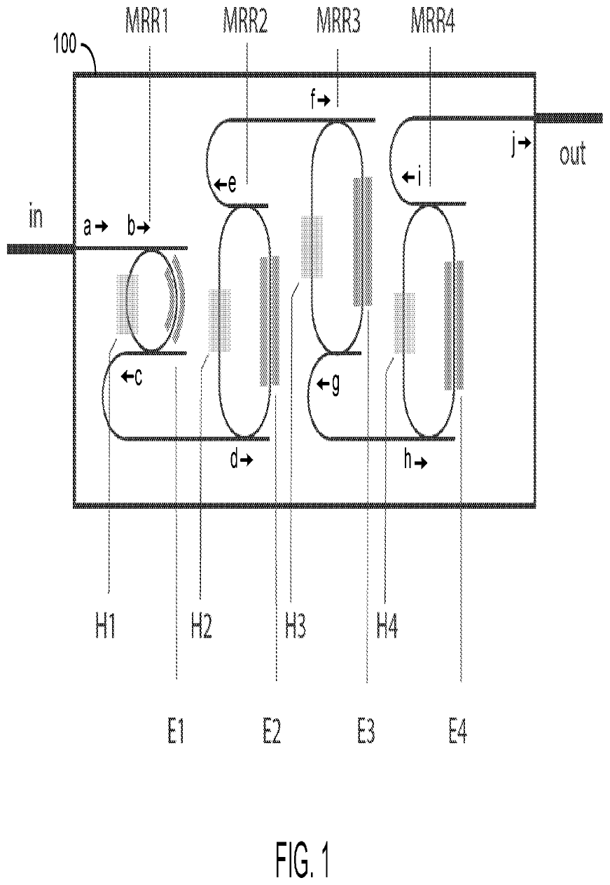

Referring to FIG. 1, an integrated photonic circuit providing rapid wavelength tuning is presented. Light is input on an optical fiber labeled “in,” connected to the TFLN integrated photonic circuit 100. Light from the fiber enters the TFLN waveguide at location “a” and travels in the indicated direction. The waveguides of the TFLN device are described by the black lines. Light is directed to a first micro-ring resonator (MRR1), which acts as a comb spectral filter. Transmission peaks that are periodic in optical frequency are output from MRR1 at location “c”. The periodicity of these transmission peaks (known as free spectral range, or FSR) is a function of the length of the resonator, as is well understood in the field. The sharpness of the transmission peaks, otherwise known as the finesse of the transmission, is determined in part by the couplers at the input and output of the MRR. Nominally, these input and output couplers are configured to be equal to each other. The light output at location “c” travels to an input to a second MRR (MRR2) at location “d” and exits MRR2 at location “e”. In a non-limiting example, light travels through a third MRR (MRR3) and fourth MRR (MRR4).

Each MRR imposes spectral filtering on the input light. In a non-limiting example, MRR2-4 are configured to have specific FSR values such that one of the transmission peaks of MRR1 travels to the output of the integrated photonic circuit, labeled “out,” with high transmission. This is analyzed within a finite optical bandwidth that can be determined by the gain bandwidth of an external optical amplifier. It should be understood that the MRR1-4 (1 passive, 3 active) spectral filter in this non-limiting example can be reduced or extended to N cascaded MRR filters, which is determined by the required filter extinction and optical bandwidth.

Each of the MRRs includes electrodes labeled as E1-E4 that allow the position of the transmission peaks for each MRR to be shifted with an applied voltage. This allows one to change which combline is transmitted through the full circuit using Vernier tuning methods. Further included in the integrated circuit are heaters, labeled H1-H4, that allow one to set the bias position of each MRR, i.e., the transmission peak locations when the applied voltage on E1-4 is zero. Heater response times are slow (milliseconds), while the electro-optic response of E1-4 is in the GHz regime. This is a consequence of the intrinsic properties of the TFLN material. Alternatively, the bias position can also be set by a DC signal applied to the electrode.

The integrated photonic circuit in FIG. 1 defines a means to use Vernier tuning principles to create a rapidly modulated spectral filter. In one embodiment, E1 is not used causing MRR1 to be “passive” and sets the frequency comb spacing of the possible outputs, while E2-E4 are used to select one of the comblines passed by E1. In another configuration, all MRRs are actively modulated to create a more agile wavelength output.

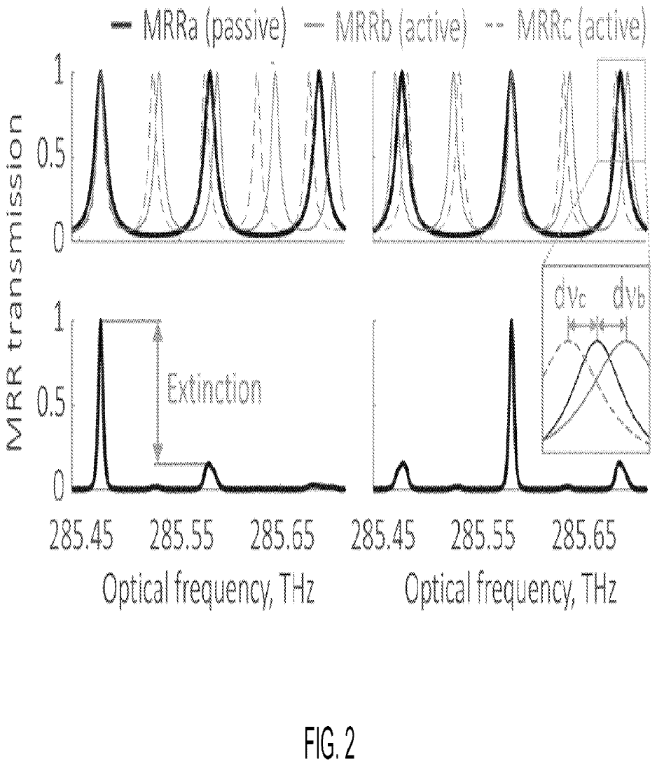

Referring now to FIG. 2, the spectral output for an MRR integrated photonic filter with three total MRRs is illustrated. In this non-limiting example, MRRa is passive (not rapidly tuned), and MRRb and MRRc are rapidly tuned. In the top left plot, the transmission response of each MRR is illustrated over three comblines of MRRa. In the bottom left plot, the combined transmission is shown, illustrating the suppression of two of the comblines. In the top right and bottom right plots, the same illustration is given for new positions of MRRb and MRRc that select a different combline of MRRa for transmission.

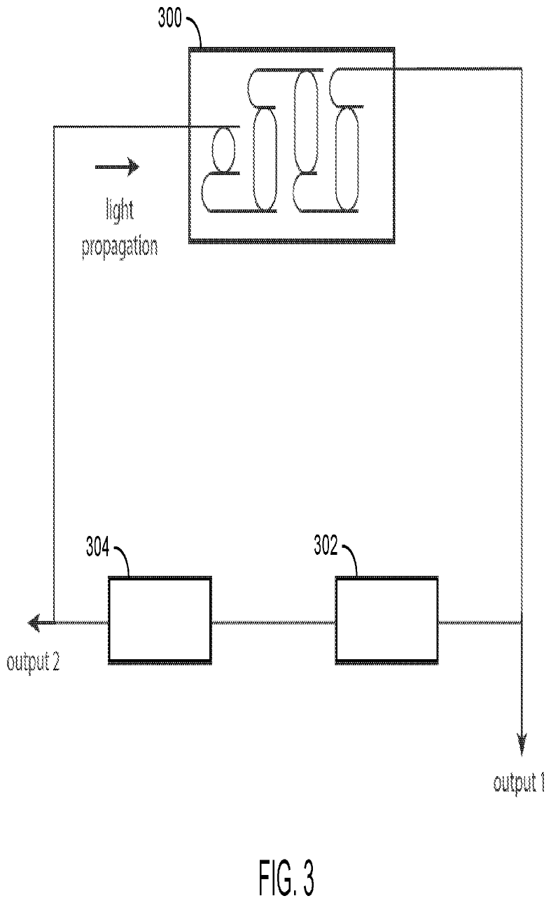

In FIG. 3, the TFLN-integrated photonic circuit is placed within a laser cavity. As used herein, the term “laser cavity” refers to an arrangement of optical elements that forms a cavity resonator for light waves. That is, the optical elements force generated light to follow a closed path. The optical output of the integrated photonic circuit 300, for example as previously described with reference to the integrated photonic circuit 100 of FIG. 1, is directed to an optical delay 302 and then directed to a gain element 304. In a non-limiting example, the optical delay 302 includes an optical fiber or free space. In a non-limiting example, the gain element 304 includes a semiconductor optical amplifier (SOA).

The amplified output of the gain element 304 is directed to the input of the integrated photonics circuit 300 to create a resonant cavity. In a non-limiting example, the drive signals provided to the integrated photonic circuit 300 can be periodic with the cavity round trip time to operate in a mode-locked resonant operation. This allows the light to be modulated at speeds that are faster than the cavity round trip time. Alternatively, the cavity round trip time can be short, and the drive signals provided to the integrated photonic circuit 300 can be slower than this shorter cavity round trip. This is an example of a short-cavity (non-resonant) laser operation.

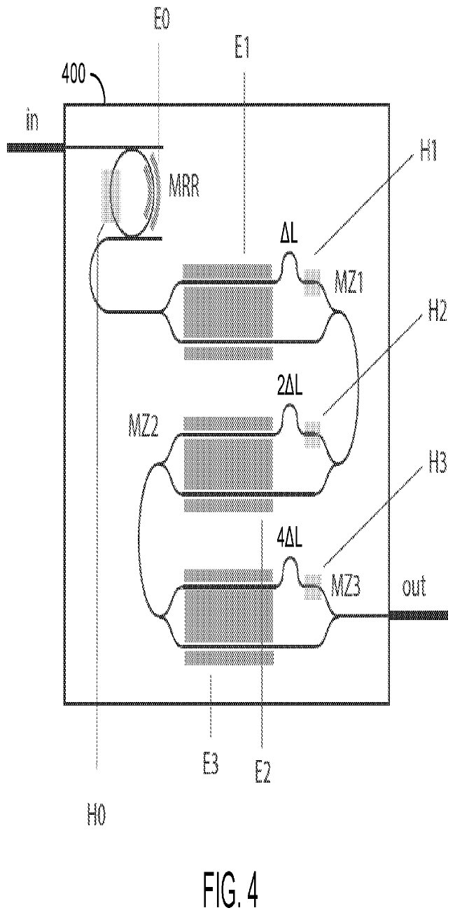

An alternative integrated photonic circuit 400 providing frequency comb spectral filtering based on tunable Mach-Zehnder (MZ) interferometers is illustrated in FIG. 4. Light is input from the “input” fiber to the circuit. An MRR provides a frequency comb filtering at a given FSR determined by the size of the MRR. The position of the frequency comb peaks can be shifted slowly using the heater HO or rapidly using the electrodes E0. This light is then directed to a first MZ filter (MZ1). Each MZ filter in the integrated photonic circuit 400 is configured to have a path imbalance between its two arms. This creates a sinusoidal spectral modulation with a spectral period (the MZ-FSR, or just FSR) that is proportional to the inverse of the path imbalance. In FIG. 4, MZ1 has a path imbalance of AL. In a non-limiting example, the integrated photonic circuit 400 is configured such that the FSR of MZ1 is twice the FSR of the MRR. Further, the FSR of MZ2 can then be four times the FSR of the MRR. Additionally, the FSR of the MZ3 can then be 8 times the FSR of the MRR. This provides an FSR scaling that follows a 2^{N} scaling where N is equal to the number of MZ filters. It can be used to select a single MRR combline out of each continuous set of 2^{N} comblines. For example, N=5 (2⁵=64) MZ filters may be used if one combline of the MRR is chosen from each continuous grouping of 64 comblines of the MRR. Note that FIG. 4 shows three MZ filters, but additional MZ filters can be appended in a straightforward way and following the pattern set by MZ1-3. Wanting to select a single MRR combline among a continuous grouping of 256 MRR comblines, would require N=8 MZ filters (2\hat{ }8=256).

The Heaters H1-H3 are used to bias the spectral tuning of each MZ filter, and the electrode connections E1-E3 allow one to rapidly shift the filter properties for each MZ. Alternatively, a DC signal applied to the electrode can be used to bias the spectral tuning of each MZ filter.

In one embodiment, a voltage signal was provided to each of E1-E3 sufficient to induce a phase shift between arms of +/−pi, which allows full tuning of the transmission peak of each MZ filter across its associated FSR.

In a non-limiting example, this integrated photonic filter 400 can be placed in a resonant cavity as described in FIG. 3, replacing the integrated photonic circuit 100, 300 of FIG. 1 with the integrated photonic filter 400 of FIG. 4.

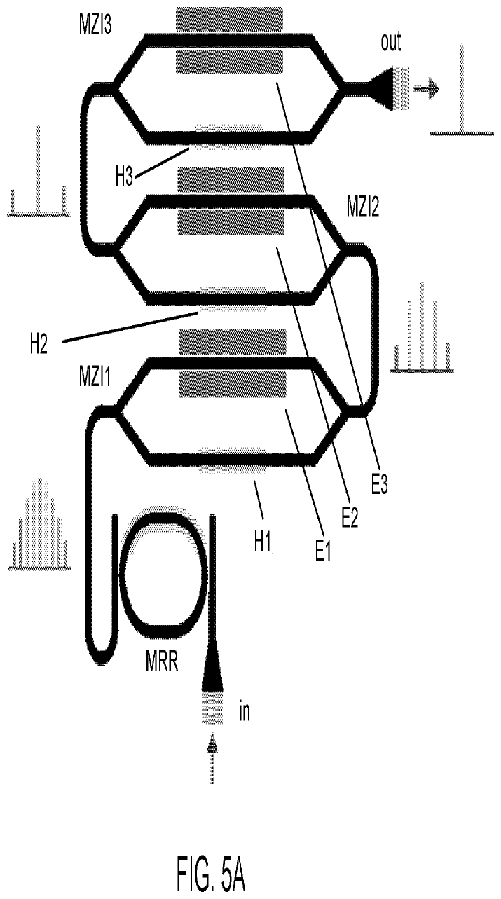

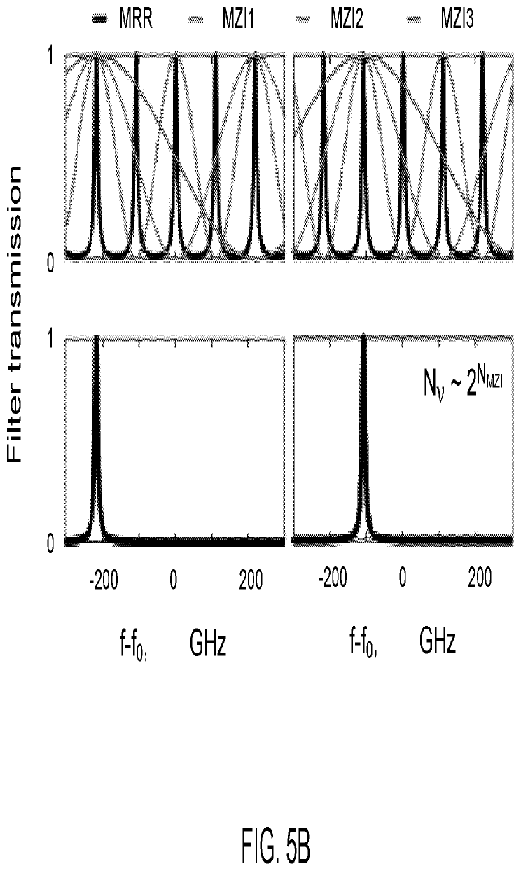

FIG. 5A-B illustrates an embodiment using a single MRR and a set of three MZ filters. This filter is configured as described by the integrated photonic circuit 400 in FIG. 4. In the top right plot of FIG. 5B, the transmission spectra of the MRR and each MZ interferometer (MZI) is shown. In a non-limiting example, the FSR of MZII is twice (2×) the FSR of the MRR, the FSR of MZI2 is four times (4×) the FSR of the MRR, and the FSR of MZI3 is eight times (8×) the FSR of the MRR. The combined transmissions are illustrated in the bottom left and right plots of FIG. 5B, each showing the selection of a single combline of the MRR.

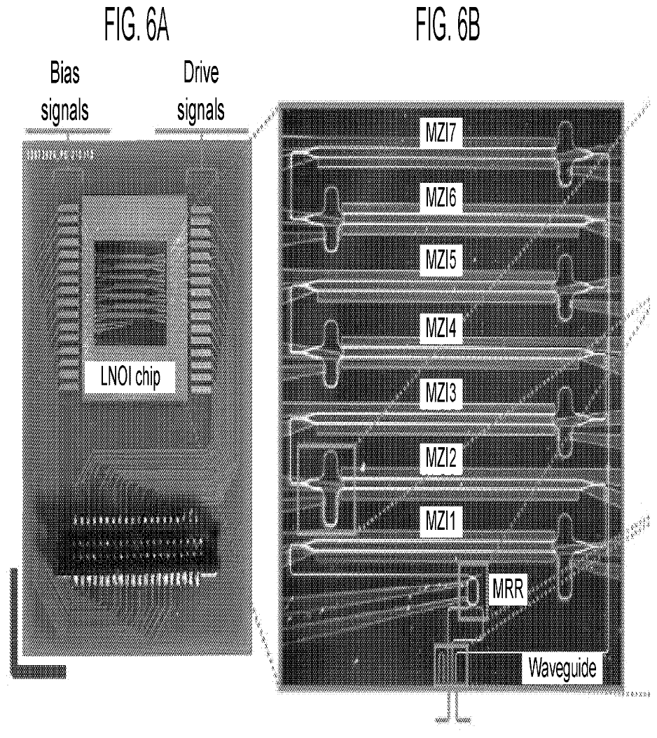

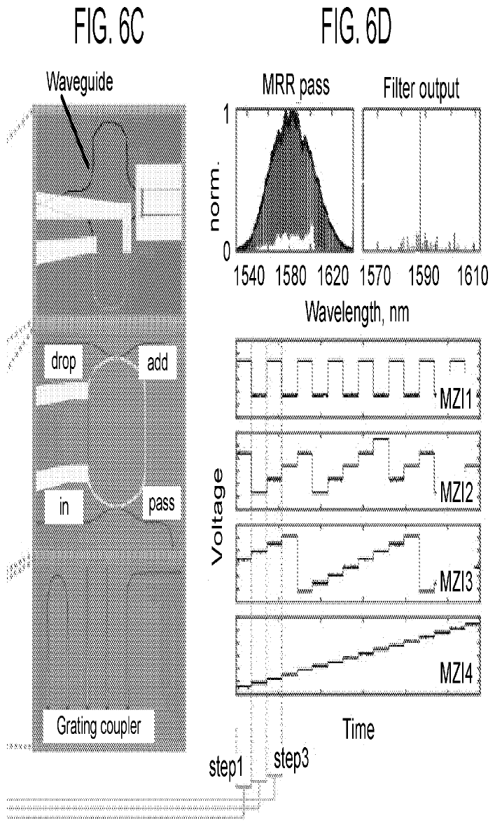

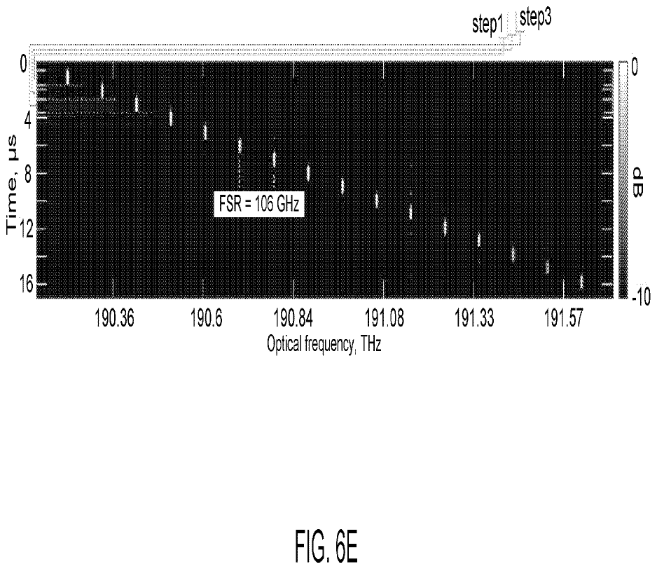

Referring now to FIGS. 6A-6E, a non-liming example of a fabricated filter device is shown. In FIG. 6A, a photograph of the fabricated integrated photonics filter (LNOI chip) is shown on an electrical interface board with electrical connections leading to a cable at the lower side of the board. The bias signals are directed to the heaters located on the MRR and each of the seven MZI filters. The drive signals connect to electrodes to modulate the light phase via the electro-optic effect.

A zoomed image of the LNOI chip is presented in FIG. 6B, showing the layout of the devices and an input/output coupling. In a non-limiting example, the input/output coupling can be achieved via a grating coupler, as in this device, or via edge coupling. FIG. 6C illustrates the electrode (E) and heater (H) overlays above the waveguides.

FIG. 6D shows the optical output after just the MRR showing a frequency comb (top row) and after the 7 MZIs showing the substantial attenuation of all but one of the MRR comblines. The drive signals for MZI1-MZI4 are shown in the lower four plots panel of FIG. 6D to achieve a monotonic stepping of the frequency of the combline. FIG. 6E shows the measured time-resolved optical output showing discrete stepping in frequency and time.

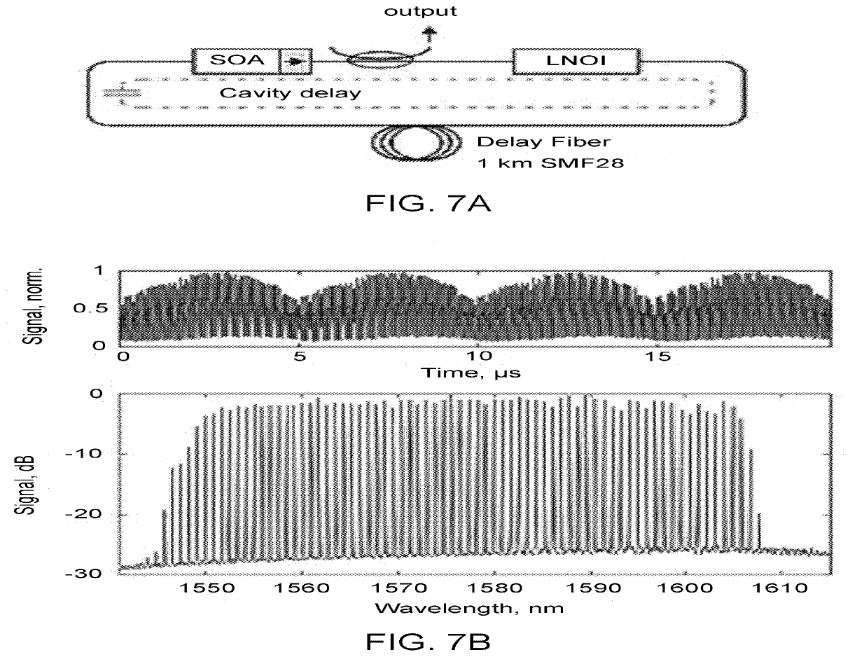

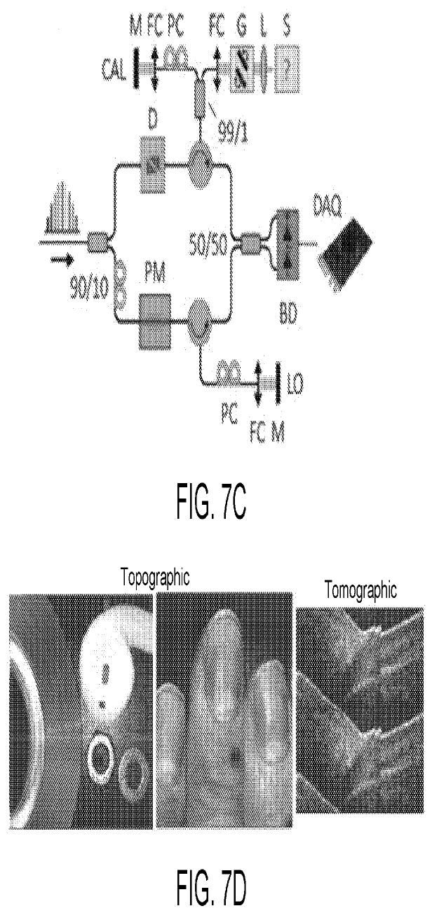

Referring now to FIGS. 7A-7D, a laser source based on a MRR and MZ integrated photonic filter is shown. In FIG. 7A, a laser cavity is shown with the filter shown in FIG. 6A represented by the LNOI. In a non-limiting example, the laser cavity includes a SOA. FIG. 7B shows the time (top plot) and spectral (bottom plot) output of the laser.

In a non-limiting example, FIG. 7C shows an imaging interferometer configuration. FIG. 7D shows exemplary en-face, topographic (left and center images) and cross-sectional, tomographic image (right image) using the source.

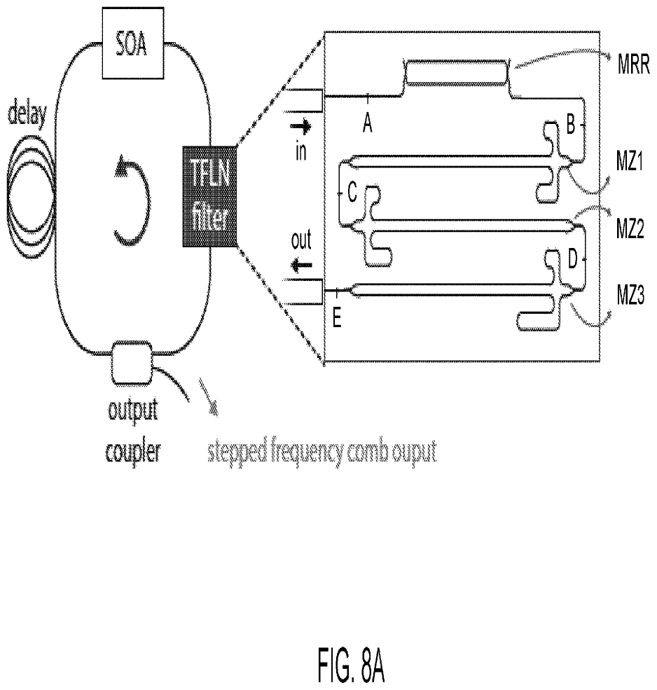

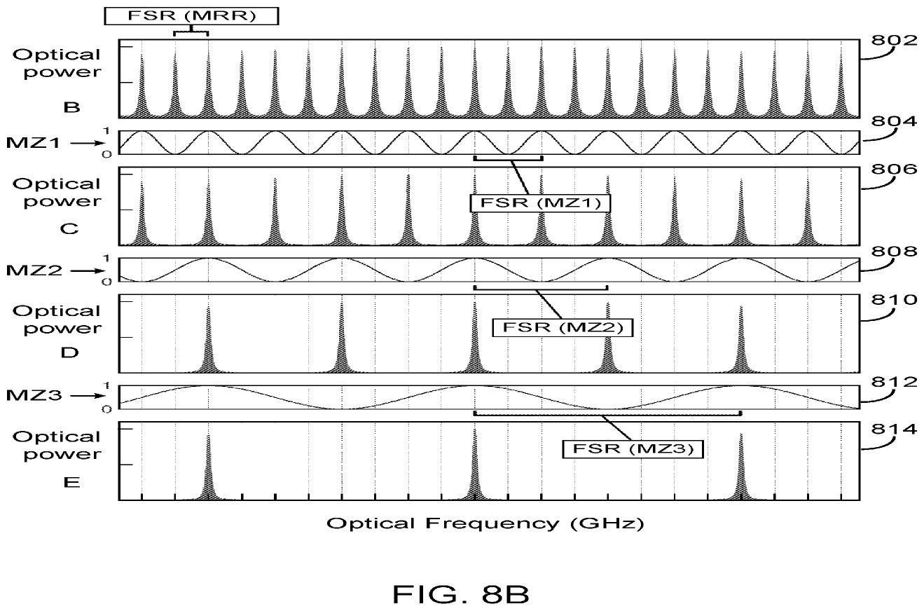

FIG. 8A presents a non-limiting example laser design incorporating a TFLN filter chip placed within a laser ring cavity. An SOA, an optical delay, and an output coupler are additionally within the ring cavity. In a non-limiting example, the SOA provides optical gain and could additionally be implemented as a doped fiber amplifier or a Raman amplifier, among other optical gain media. The delay can be a length of optical fiber or other suitable optical delay, as described previously. In a non-limiting example, the output coupler can be a simple beamsplitter providing a portion of light as output and a portion is maintained within the ring.

The overall cavity round trip time can be configured to be resonant with the TFLN filter state such that light circulating in the cavity sees substantially the same TFLN filter state on successive passes through the filter. Light traveling counter-clockwise is directed to the TFLN input (“in”). This light is directed to the MRR, followed by MZ1 filter, MZ2, and MZ3. Light exiting MZ3 exits the output (“out”) and returned to the ring cavity, where it is directed to the SOA.

FIG. 8B shows the optical spectrum of broadband amplified spontaneous emission light at locations B, C, D, and E in the TFLN filter. This illustrated embodiment assumes the TFLN filter is configured to a particular state by controlling the phase properties of the MRR and the MZ1-4. The light exiting the MRR (B) shows a frequency comb spectrum 802 with the spacing between comb lines given by the FSR of the MRR. The sinusoidal spectral transmission of MZ1 804 is shown with the free spectral range of the MZ1 (labeled FSR (MZ1)). Here, FSR (MZ1) is configured to be twice FSR (MRR) leading to a filtering out of half of the comb lines as shown in panel 806 showing the light at location (C). 808 shows the sinusoidal spectral transmission of MZ2 with FSR (MZ2) configured to be twice FSR (MZ1). Panel 810 shows the resulting transmitted light at location (D). Panel 812 shows the sinusoidal spectral transmission of MZ3 with FSR (MZ3) configured to be twice FSR (MZ2), with the resulting output E shown in panel 814. Note that in this configuration wherein the MZ FSR is configured to be 2×, 4×, and 8× the FSR of the MRR removes completely half of the comblines at each MZ. A laser design with this FSR relationship thus can uniquely pass one out of every 2^{N} comblines where N is the number of MZ filters. If the optical gain bandwidth of the laser cavity is narrower than the spectral bandwidth of N comb lines, then this design can be used to force the laser to lase in a particular combline. Note that if the TFLN is modulated by controlling the phase of the MZ filters and, optionally, the MRR, then laser wavelength can be tuned. Note that at least some of the MZ filters used in FIG. 8 are path-imbalanced, i.e., have one arm that is longer than the other arm, resulting in a sinusoidal spectral transmission with a particular FSR that depends on the path-imbalance.

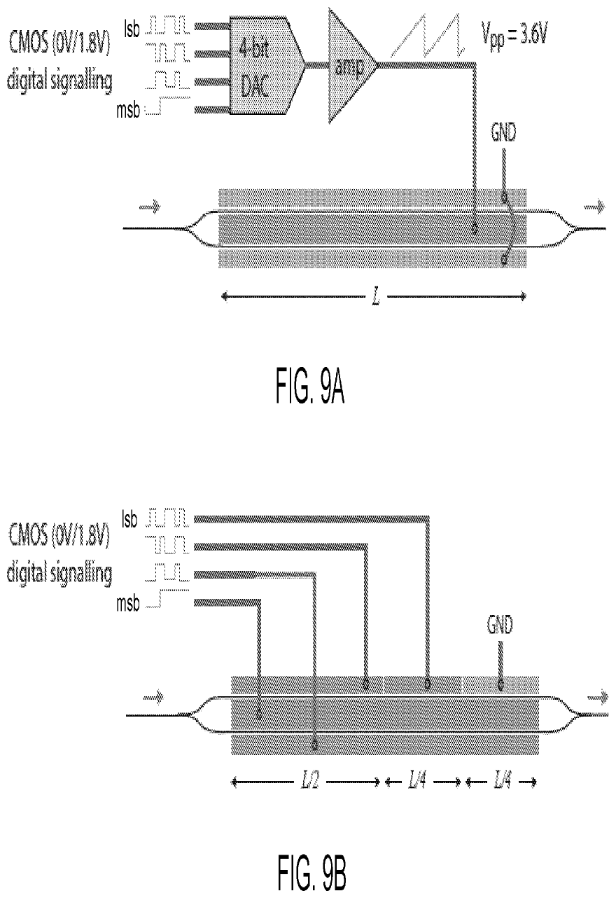

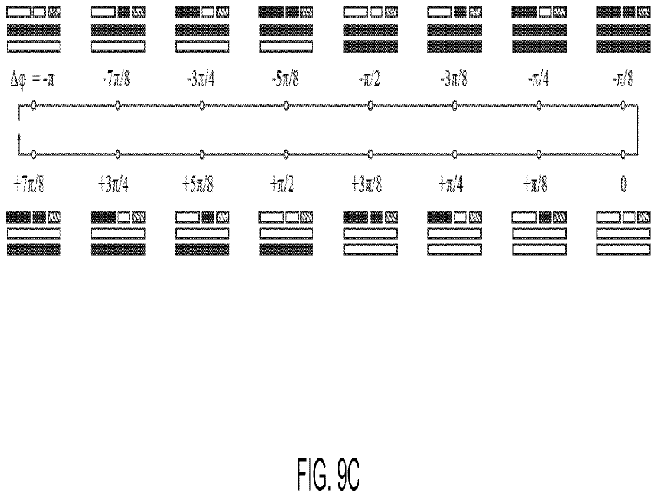

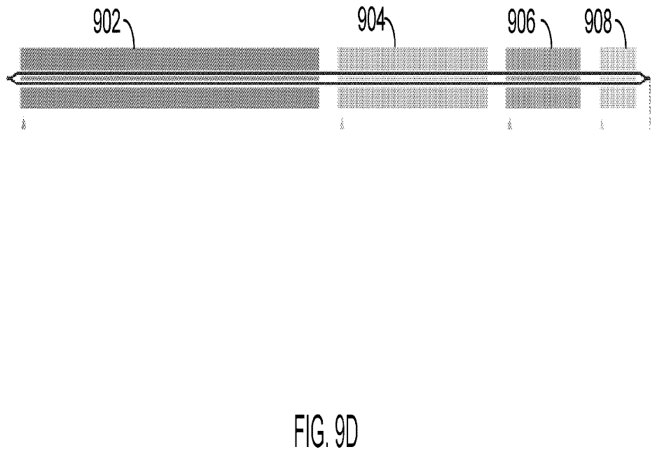

FIG. 9A shows a conventional electro-optically controllable MZ filter that is based on an analog drive signal with a peak-to-peak voltage range of 3.6 V. Here, the analog voltage is applied to an inner electrode between the two MZ arms in what is known as a push-pull operation where a positive phase shift is induced in the upper arm, and a negative phase shift is induced in the lower arm or vice versa. The induced phase shift between the upper and lower MZ arms is a function of the voltage signal applied to the inner electrode. In a non-limiting example, to create a variable voltage signal, a digital-to-analog converter (DAC) is used, followed by an RF amplifier as required to achieve the voltage range (in this example, 3.6 Vpp). In this example, a 4-bit DAC is used and controlled by 4 separate digital lines communicated to that DAC in 4 parallel lines with CMOS (0/1.8 V) signaling. Light is launched from the left and exits on the right. The electrode length is L.

FIG. 9B shows an MZ filter that is electro-optically controllable by a digital control signal, i.e., by electrical signals that can take two voltage values. In this example, an assumed voltage state of 1.8 V and 0 V is used. FIG. 9B shows an electro-optically controllable MZ filter that does not require a DAC but instead performs the digital-to-analog conversion in the optical domain using a sequence of electrodes with specific placements and lengths. There are 3 independent electrodes of length L/4, L/4, and L/2 above the upper MZ arm. One of these electrodes can be connected to ground (GND) and not controlled by a digital signal. The other L/4 length electrode is connected to the least significant bit (LSB) of the 4-bit digital signal. The L/2 length electrode is connected to the second to least significant bit. A fourth electrode of length L is located between the MZ arms and is connected to the most significant bit (MSB). A fifth electrode of length L is located below the lower arm and is connected to the second most significant bit. Although the MZ filter shown in FIG. 9B does not indicate that it is path-imbalanced, this digital control of the phase of a MZ can be used to control both a path-balanced MZ acting as an intensity modulator and a path-imbalanced MZ acting as a spectral filter. This digital control can be applied to one or more of the MZ filters as shown in FIG. 8A, FIG. 6B, FIG. 5A, or FIG. 4. In addition, the digitally controllable MZ of FIG. 9B shows a 4-bit control with 2⁴=16 phase settings equally distributed across the unit circle. It can be understood that this same design can be extended to have N-bits of resolution, providing 2^{N} phase settings equally distributed across the unit circle.

FIG. 9C shows the digital encoding table to create 2⁴=16 phase differences in the MZ filter from −π, −7π/8, . . . , +7π/8. In this encoding table, a grey rectangle denotes an electrode that is driven at 1.8 V, a white rectangle denotes an electrode driven at 0 V, and one of the electrodes (with dashed lines) is configured to be connected directly to the ground (0 V).

This design allows the MZ filter to be electro-optically controlled directly from a digital CMOS signal without requiring digital to analog conversion in the electrical domain, thereby simplifying the drive electronics and improving the switching bandwidth. In some configurations for example, the digital CMOS signals can be driven at 1 Gbit/second modulation speeds, or at 10 Gbit/second modulation speeds.

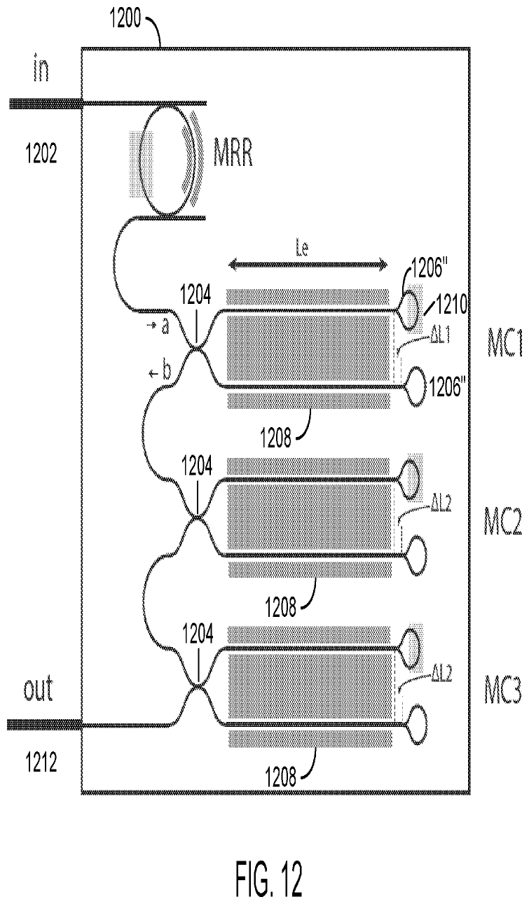

FIG. 9D shows an alternative electrode geometry for the digital control of an MZ interferometer. In this non-limiting example, four electrode arrangements 902, 904, 906, and 908 are included. The electrode arrangement 904 is designed to have half the length of 902. The electrode arrangement 906 is designed to have half the length of 904. The electrode arrangement 908 is designed to have half the length of 906. This allows digital control, with electrode arrangement 908 being associated with the least significant bit in a 4-bit parallel digital signal and electrode arrangement 902 being associated with the most significant bit. In FIG. 9D, a given electrode arrangement such as 902 904, 906, or 908 can be configured as push-pull wherein an electrode is located between the upper and lower arms of the MZ, an electrode is located above the upper arm, and an electrode is located below the lower arm. It can be further configured such that the electrode above the upper arm and the electrode below the lower arm are connected and modulated together. This connection can be either on the integrated chip or within the electrical drive circuits. It can be further understood that there are additional electrode geometries that can be used to induce phase differences between the two arms of the MZ or Michelson (see FIG. 12 for an example of a Michelson interferometer design). Common to these geometries is the use of a set of distinct electrodes within the interferometer, where the electrodes are connected to digital (binary) electrical signals and where the specific pattern of digital electrical signals delivered to the set of electrodes allows the induced phase different to take on different values. In some embodiments of the invention, the number of electrodes within the interferometer that can be independently controlled by a digital signal is greater than 2. For example, the number of controllable (able to be electrically modulated) electrodes in FIG. 9B is 4 (not including the one ground electrode). And for example, the number of controllable electrodes in FIG. 9D can be 4 if all the electrodes above the upper arm and below the lower arm are connected to a common and unchanging voltage and only the electrodes between the arms of the MZ can be digitally modulated, or it can be 12 if every electrode above the upper can be controlled, every electrode between the MZ arms can be controlled, and every electrode below the lower arm can be controlled.

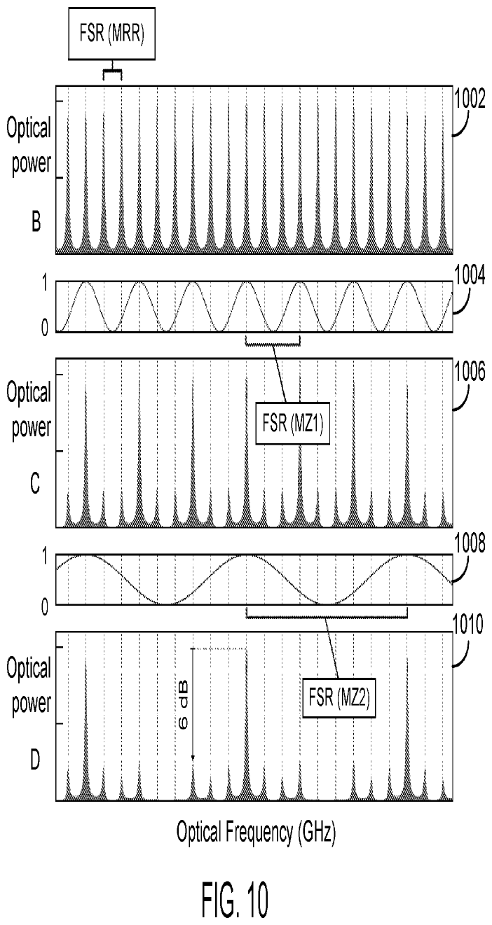

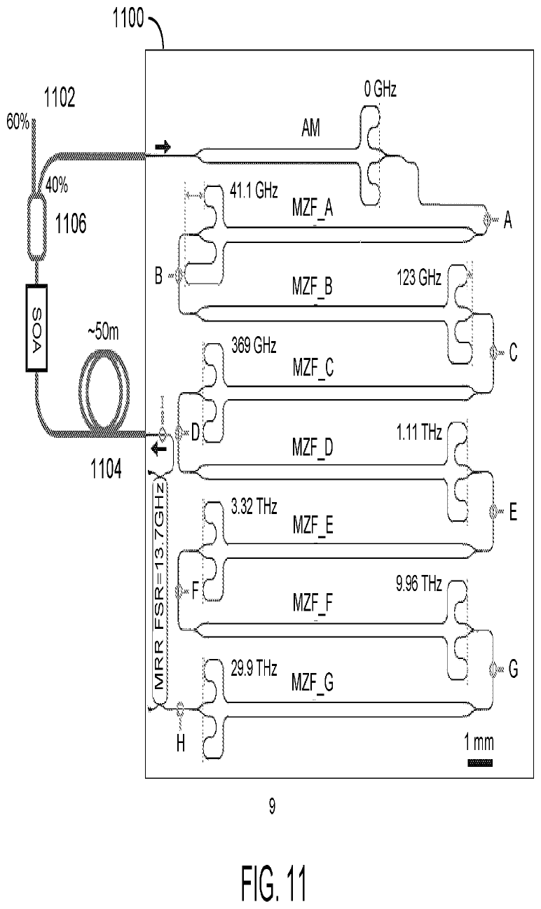

FIG. 10 shows a cascaded MZ filter configured with MZ FSRs that are powers of three of the MRR FSR, i.e., where the first MZ filter has an FSR of 3× (FSR (MRR)), the second MZ filter has an FSR of 9× (FSR (MRR)), etc. The MRR output frequency comb is shown in panel 1002. The transmission of MZ1 in shown in 1004, and the resulting transmitted spectrum is shown in 1006. Note that in comparison to the configuration in FIG. 8, the output of each MZ can include some residual power in each frequency comb. After MZ2 (transmission of MZ2 is shown in 1008), the output (shown in panel 1010) has selected every 9th combline, with partial but not complete rejection of the intervening comblines. Thus, this configuration can be used to create and select one combline within 3^{N} comblines where N is the number of MZ filters, albeit with less extinction in its filter rejection. However, because the TFLN filter is being used within a laser cavity, it is not essential that the filter provide high extinction and relatively moderate extinction, which is the difference in transmission between the intended combline and any unintended combline, such as 6 dB can be sufficient to force the laser to operate at the desired combline. Thus, in panel 1010, this filter provides 6 dB extinction. The advantage of this design is that for a given number of MZ filters, the TFLN filter chip can select amongst a much larger set of comblines, i.e., 3^{N} versus 2^{N}. For example, for N=5, this is the difference between 3\hat{ }5=243 and 2\hat{ }5=32, or between 729 and 64 for N=6. Note that this example uses MZ FSRs that are a power of 3 relative to the MRR FSR. However, it can be appreciated that the same principle can be used for other FSRs, such as having the FSR of the i^{th} MZ, FSR_i=2.78ⁱ or FSR_i=4ⁱ. Thus, in some embodiments the filter can have a FSR that is a power of 2, 3, 4, or any other value. Alternatively, the FSRs of the MZs can be configured not to have a specific power-law scaling but rather be selected to optimize filter transmission properties.

Referring now to FIG. 11, a laser cavity with a TFLN filter chip is shown using a MRR and cascaded set of path-imbalanced MZs following a power of three scaling. The laser comprises the TFLN chip 1100 in a ring cavity 1102 with delay 1104, an SOA, and an output coupler 1106. The light entering the TFLN is directed to an amplitude modulator (AM) which is an MZ without a path imbalance. The AM can be used to create source amplitude pulsation. This can be used to suppress light transmission during the time in which the voltage signal applied to the path-imbalanced MZ filters is changing, and to pass light during the time in which the voltage signal applied to the path-imbalanced MZ filters is stable. In other words, this can be used to prevent the laser from generating light during the transition times of the TFLN filter. The light is then directed to a cascade of MZ path imbalanced filters MZF_A to MZF_G with FSRS of 41.1 GHz to 29.9 THz according to a power of three scalings.

In FIG. 12, an alternative filter design 1200 based on Michelson interferometers is presented. Here, light at the input 1202 is transmitted to the MRR, and light exiting the MRR is directed to location a, where it is input to the first Michelson interferometer (MC1). In this embodiment, a directional (2×2) coupler 1204 provides light to an upper and lower arm. Each arm is terminated by a Sagnac loop mirror (1206′, 1206″), which acts as a broadband optical reflector. An electrode structure 1208 provides voltage-controlled phase modulation in a manner that is similar to the MZ electrodes of FIG. 4. A heater 1210 can be located to provide slow-tuning phase control. The Michelson interferometer can be configured with a path imbalance ΔL1, providing a spectral sinusoidal modulation with an FSR that is inversely related to the path imbalance in a manner similar to the MZ design. The light output on port b is directed to further Michelson interferometers MC2 and MC3, although it can be appreciated that the number of Michelson interferometers can be changed, for example, to have between 1 and 12 Michelson interferometers. The light can be output on 1212. This integrated photonic filter can be incorporated into a laser cavity such as that provided in FIG. 7A and operated analogous to the embodiments using MRR with MZ filters. The advantage of the Michelson interferometer design is that the integrated photonic area can be reduced by double-passing the light through the electrode, thereby achieving the same phase shift range with half of the electrode length. The electrode design in the Michelson interferometers is shown as being compatible with an analog voltage signal but can be designed according to FIG. 9B or FIG. 13 to allow digital control.

It can be understood that although the present embodiments are based on the use of a lithium-niobate electro-optic material, the embodiments can additionally employ other electro-optic materials such as lithium tantalite, potassium titanyl, phosphate, ß-barium borate, and/or the like.

While the particular embodiments present the components of the TFLN filter in a particular order, it can be understood that alternative orders are possible such as for example light first going to MZ 1 in FIG. 8a, then to the MRR, then to MZ2, then to MZ3. Likewise, the order of the optical gain element, delay, output coupler, and TFLN inside the laser cavity can be altered and still provide substantially the same performance. In addition, it can be understood that the laser cavities of FIG. 8a, FIG. 11, FIG. 7A, and FIG. 3 are presented as ring cavities, but that the invention can be implemented in a linear cavity design wherein at least one of the TFLN filter or optical gain is used bidirectionally.

Although the presented embodiments illustrate each MRR, MZ, or MC interferometer with both an electrode (or set of electrodes) and a heater, it can be understood that not every MRR, MZ, or MC interferometer needs to have both an electrode (or set of electrodes) and a heater. Instead, a photonic circuit can be configured such that a given interferometer may have just an electrode (or electrode arrangement) without a heater, may have just a heater without an electrode (or electrode arrangement), or may have neither a heater nor electrode (or electrode arrangement), i.e., may be a passive element. In such cases, the remaining interferometer(s) in the photonic circuit can be tuned relative to the passive element(s) in the circuit.

While the invention has been disclosed in particular embodiments, it will be understood by those skilled in the art that certain substitutions, alterations and/or omissions may be made to the embodiments without departing from the spirit of the invention. Accordingly, the foregoing description is meant to be exemplary only, and should not limit the scope of the invention. All references, scientific articles, patent publications, and any other documents cited herein are hereby incorporated by reference for the substance of their disclosure.

What is claimed is:

1. An integrated photonic circuit, comprising:
an input and an output;
a plurality of micro-ring resonators (MRRs) disposed between the input and the output, each of the plurality of MRRs including an electrode and a heater,
each electrode being configured to shift a position of a transmission peak of an input transmission and each heater being configured to set a location of the transmission peak when a voltage at the electrode is zero, the MRRs including:
a first MRR coupled to the input, the first MRR including a first heater and a first electrode, and
a second MRR coupled to the output, the second MRR including a second heater and a second electrode; and
a controller coupled to the first heater, the first electrode, the second heater, and the second electrode, the controller being configured to:
control at least one of the first heater, the first electrode, the second heater, or the second electrode to emit light with a transmission peak at the output.

2. The circuit of claim 1, further comprising a third MRR disposed between the second MRR and the output.

3. The circuit of claim 2, further comprising a fourth MRR disposed between the second MRR and the output.

4. The circuit of claim 1, wherein the controller is further configured to control the at least one of the first heater and first electrode to modulate a transmission frequency and a periodicity of the input transmission directed into the first MRR.

5. The circuit of claim 4, wherein the controller is further configured to control at least one of the second heater and second electrode to further modulate the transmission frequency and periodicity of the input transmission directed into the second MRR from the first MRR.

6. The circuit of claim 5, wherein an output transmission at the output includes a single transmission peak from the first MRR.

7. The circuit of claim 1, wherein a voltage to the first electrode is zero thereby making the first MRR passive.

8. A laser cavity, comprising:
the integrated photonic circuit of claim 1;
a delay; and
a gain, wherein the integrated photonic circuit, delay, and gain are positioned in series within the laser cavity.

9. The laser cavity of claim 8, wherein the delay includes an optical fiber or free space optics.

10. The laser cavity of claim 8, wherein the gain includes semiconductor optical amplifier (SOA).

11. The laser cavity of claim 8, wherein an amplified output of the gain is directed to the input of the integrated photonic circuit to create a resonant cavity.

12. The laser cavity of claim 11, wherein the controller of the integrated photonic circuit is configured to provide drive signals that are periodic with a cavity round-trip time of the transmission for a mode-locked resonant operation.

13. An integrated photonic circuit, comprising:
an input and an output;
a micro-ring resonator (MRR) disposed between the input and the output, including an electrode and a heater, wherein the electrode is configured to shift the position of transmission peaks of an input transmission and the heater is configured to set the location of the transmission peaks when a voltage to the electrodes is zero, the MRR including:
an MRR coupled to the input, the MRR including a heater and an electrode;
a plurality of Mach-Zehnder (MZ) filters disposed between the MRR and the output and configured to receive the transmission from the MRR, the MZ filters including:
two arms of differing lengths to create a path imbalance between them; and
a controller coupled to the heater and the electrode, the controller being configured to:
control at least one of the heater or the electrode to emit light with a transmission peak at the output.

14. The circuit of claim 13, wherein each of the plurality of MZ filters is configured to create a sinusoidal spectral modulation with a spectral period that is proportional to an inverse of the path imbalance (AL).

15. The circuit of claim 14, wherein the spectral period of a first MZ filter is twice the spectral period of the MRR.

16. The circuit of claim 15, wherein the spectral period of a second MZ filter is four times the spectral period of the MRR.

17. The circuit of claim 16, wherein the spectral period of a third MZ filter is eight times the spectral period of the MRR.

18. The circuit of claim 13, wherein each of the plurality of MZ filters further includes an electrode and a heater, and
wherein the electrode is configured to shift the position of transmission peaks of the transmission from the MRR and the heater is configured to set the location of the transmission peaks when a voltage to the electrodes is zero.

19. The circuit of claim 13, wherein a plurality of independent electrodes are connected to one of a pair of arms of each MZ filter, the electrodes configured to electro-optically control the each of the plurality of MZ filters by performing a digital to analog conversion in an optical domain.

20. The circuit of claim 13, wherein each of the plurality of MZ filters are configured to have transmission peak periodicities in powers of two of the MRR transmission peak periodicity.

21. The circuit of claim 13, wherein each of the plurality of MZ filters are configured to have transmission peak periodicities in powers of three of the MRR transmission peak periodicity.

22. A method of operating an integrated photonic circuit, comprising:
providing an integrated photonic circuit comprising:
an input and an output,
a plurality of micro-ring resonators (MRRs) disposed between the input and the output,
each of the plurality of MRRs including an electrode and a heater,
each electrode being configured to shift a position of a transmission peak of an input transmission and each heater being configured to set a location of the transmission peak when a voltage at the electrode is zero, and the MRRs including:
a first MRR coupled to the input, the first MRR including a first heater and a first electrode, and
a second MRR coupled to the output, the second MRR including a second heater and a second electrode;
coupling a controller to the first heater, the first electrode, the second heater, and the second electrode; and
controlling, using the controller, at least one of the first heater, the first electrode, the second heater, or the second electrode to emit light with a transmission peak at the output.

23. The method of claim 22, further comprising:
disposing a third MRR between the second MRR and the output.

24. The method of claim 23, further comprising:
disposing a fourth MRR disposed between the second MRR and the output.

25. The method of claim 22, further comprising:
controlling the at least one of the first heater and first electrode to modulate a transmission frequency and a periodicity of the input transmission directed into the first MRR.

26. The method of claim 25, further comprising:
controlling at least one of the second heater and second electrode to further modulate the transmission frequency and periodicity of the input transmission directed into the second MRR from the first MRR.

27. The method of claim 26, wherein an output transmission at the output includes a single transmission peak from the first MRR.

28. The method of claim 22, wherein a voltage to the first electrode is zero thereby making the first MRR passive.

29. A method of operating a laser cavity, comprising:
providing the integrated photonic circuit of claim 22; and
positioning the integrated photonic circuit, a delay, and a gain in series within the laser cavity.

30. The method of claim 29, wherein the delay includes an optical fiber or free space optics.

31. The method of claim 29, wherein the gain includes semiconductor optical amplifier (SOA).

32. The method of claim 29, further comprising,
directing an amplified output of the gain to the input of the integrated photonic circuit to create a resonant cavity.

33. The laser cavity of claim 32, further comprising:
using the controller of the integrated photonic circuit to provide drive signals that are periodic with a cavity round-trip time of the transmission for a mode-locked resonant operation.

34. A method of operating an integrated photonic circuit, comprising:
providing an integrated photonic circuit comprising:
an input and an output;
a micro-ring resonator (MRR) disposed between the input and the output, including an electrode and a heater, the electrode being configured to shift a position of a transmission peak of an input transmission and the heater being configured to set a location of the transmission peak when a voltage to the electrode is zero, the MRR being coupled to the input, the MRR including a heater and an electrode;
disposing a plurality of Mach-Zehnder (MZ) filters between the MRR and the output,
the MZ filters being configured to receive the transmission from the MRR, the MZ filters including two arms of differing lengths to create a path imbalance between them;
coupling a controller the heater and the electrode; and
controlling, using the controller, at least one of the heater or the electrode to emit light with a transmission peak at the output.

35. The method of claim 34, further comprising:
creating, using each of the plurality of MZ filters, a sinusoidal spectral modulation with a spectral period that is proportional to an inverse of the path imbalance (AL).

36. The method of claim 35, wherein the spectral period of a first MZ filter is twice the spectral period of the MRR.

37. The method of claim 36, wherein the spectral period of a second MZ filter is four times the spectral period of the MRR.

38. The method of claim 37, wherein the spectral period of a third MZ filter is eight times the spectral period of the MRR.

39. The method of claim 34, wherein each of the plurality of MZ filters further includes an electrode and a heater, and
wherein the method further comprises at least one of:
shifting, using the electrode, the position of the transmission peak of the transmission from the MRR, or
setting, using the heater, the location of the transmission peak when the voltage to the electrode is zero.

40. The method of claim 34, further comprising:
connecting a plurality of independent electrodes to one of a pair of arms of each MZ filter of the plurality of MZ filters, and
electro-optically controlling, using the electrodes, each of the plurality of MZ filters by performing a digital to analog conversion in an optical domain.

41. The method of claim 34, further comprising:
configuring each of the plurality of MZ filters to have transmission peak periodicities in powers of two of the MRR transmission peak periodicity.

42. The method of claim 34, further comprising:
configuring each of the plurality of MZ filters to have transmission peak periodicities in powers of three of the MRR transmission peak periodicity.

43. An integrated photonic circuit, comprising:
an input and an output;
a plurality of micro-ring resonators (MRRs) disposed between the input and the output, each of the plurality of MRRs including an electrode,
each electrode being configured to shift a position of a transmission peak of an input transmission and to set a location of the transmission peak, the MRRs including:
a first MRR coupled to the input, the first MRR including a first electrode, and
a second MRR coupled to the output, the second MRR including a second electrode; and
a controller coupled to the first electrode and the second electrode, the controller being configured to:
control at least one of the first electrode or the second electrode to emit light with a transmission peak at the output.

44. The circuit of claim 43, further comprising a third MRR disposed between the second MRR and the output.

45. The circuit of claim 44, further comprising a fourth MRR disposed between the second MRR and the output.

46. The circuit of claim 43, wherein the controller is further configured to control the first electrode to modulate a transmission frequency and a periodicity of the input transmission directed into the first MRR.

47. The circuit of claim 46, wherein the controller is further configured to control the second electrode to further modulate the transmission frequency and periodicity of the input transmission directed into the second MRR from the first MRR.

48. The circuit of claim 47, wherein an output transmission at the output includes a single transmission peak from the first MRR.

49. The circuit of claim 43, wherein a voltage to the first electrode is zero thereby making the first MRR passive.

50. An integrated photonic circuit, comprising:
an input and an output;
a plurality of micro-ring resonators (MRRs) disposed between the input and the output,
the MRRs including:
a first MRR coupled to the input, the first MRR including a first heater and a first electrode, and
a second MRR coupled to the output, the second MRR including a second heater and a second electrode,
the first electrode and the second electrode being configured to shift a position of a transmission peak of an input transmission, and
the first heater and the second heater being configured to set a location of the transmission peak when a voltage at the electrode is zero; and
a controller coupled to the first heater, the first electrode, the second heater, and the second electrode, the controller being configured to:
control at least one of the first heater, the first electrode, the second heater, or the second electrode to emit light with a transmission peak at the output.

51. The circuit of claim 50, further comprising a third MRR disposed between the second MRR and the output.

52. The circuit of claim 51, further comprising a fourth MRR disposed between the second MRR and the output.

53. The circuit of claim 50, wherein the controller is further configured to control the at least one of the first heater and first electrode to modulate a transmission frequency and a periodicity of the input transmission directed into the first MRR.

54. The circuit of claim 53, wherein the controller is further configured to control at least one of the second heater and second electrode to further modulate the transmission frequency and periodicity of the input transmission directed into the second MRR from the first MRR.

55. The circuit of claim 54, wherein an output transmission at the output includes a single transmission peak from the first MRR.

56. The circuit of claim 50, wherein a voltage to the first electrode is zero thereby making the first MRR passive.

57. The circuit of claim 50, further comprising a third MRR, wherein the third MRR does not have a heater or an electrode.
